(19) United States
(12) Patent Application Publication
(10) Pub. No.: US 2009/0114983 A1
(43) Pub. Date: May 7, 2009

(54) Power Transistor Capable of Decreasing Capacitance between Gate and Drain

(76) Inventors: Wei-Chieh Lin, Hsinchu City (TW); Jen-Hao Yeh, Kaohsiung County (TW); Ming-Jang Lin, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/142,802

(22) Filed: Jun. 20, 2008

Related U.S. Application Data
(60) Provisional application No. 60/985,289, filed on Nov. 5, 2007.

(51) Int. Cl. H01L 29/78

(52) U.S. Cl. 257/333; 257/E29.262

(57) ABSTRACT

A power transistor capable of decreasing capacitance between a gate and a drain includes a backside mental layer, a substrate formed on the backside mental layer, a semiconductor layer formed on the substrate, and a frontside mental layer formed on the semiconductor layer. The semiconductor layer comprises a first trench structure comprising a gate oxide layer, a second trench structure comprising a p-well junction formed around a second trench, a p-body region formed outside the first trench structure and the second trench structure, a first n+ source region formed on the p-body region and beside a sidewall of the first trench structure, a second n+ source region formed on the p-body region and between another sidewall of the first trench structure and the second trench structure, and a dielectric layer formed on the first trench structure, the first n+ source region, and the second n+ source region.

### CROSS REFERENCE TO RELATED APPLICATIONS

This application claims the benefit of U.S. Provisional Application No. 60/985,289, filed on Nov. 5, 2007 entitled “Novel Junction Pinch Power Device”, the contents of which are incorporated herein by reference.

### BACKGROUND OF THE INVENTION

1. Field of the Invention

The present invention relates to a power transistor capable of decreasing capacitance between gate and drain, and more particularly, to a power transistor capable of increasing the depth of the depletion region via trench structures beside gate, so as to decrease capacitance between gate and drain.

2. Description of the Prior Art

A trench power transistor is a typical semiconductor device in power management application, such as switching power supply, power control IC of a computer system or peripherals, power supply of a backlight, motor controller, etc. The major criteria for selecting power devices are power loss and power dissipation. In practice, resistance loss and switching loss between transient current and voltage waveforms dominate power loss of a power device. Therefore, to solve the above-mentioned problem, capacitance and charges of the trench power transistor need to be decreased. Besides, in the trench power transistor, the capacitance and charges are positively related. That is, the greater the capacitance is, the greater the charges are. The switching speed of gate is affected by the charges, which becomes slower as the chargers become greater, and faster as the chargers become smaller. Certainly, the fast switching speed is expected.

In order to gain the faster switching speed, the prior art provides modifications on the structure of the trench power transistor to reduce capacitance and charges. For example, U.S. Pat. No. 6,084,264 discloses a trench MOSFET having a thicker bottom oxide for decreasing gate capacitance. U.S. Pat. No. 6,291,298 discloses a trench semiconductor device decreasing gate capacitance via combinations of materials with different dielectric constants. Furthermore, structures as disclosed in U.S. Pat. No. 6,979,621 and No. 5,801,417 deepen trenches by floating gate, so as to decrease capacitance. However, via the above-mentioned structures, production costs are increased, and manufacturing processes are complicated. In addition, the depths of the trenches cannot be easily controlled, causing unstable situations.

### SUMMARY OF THE INVENTION

It is therefore a primary objective of the claimed invention to provide a power transistor capable of decreasing capacitance between gate and drain.

The present invention discloses a power transistor capable of decreasing capacitance between a gate and a drain, which comprises a backside mental layer, a substrate formed on the backside mental layer, a semiconductor layer formed on the substrate, and a frontside mental layer formed on the semiconductor layer. The semiconductor layer comprises a first trench structure comprising a gate oxide layer formed around a first trench with poly-Si implant, a second trench structure comprising a p-well junction formed around a second trench with conductive material implant, a p-body region formed outside the first trench structure and the second trench structure, a first n+ source region formed on the p-body region and beside a sidewall of the first trench structure, a second n+ source region formed on the p-body region and between another sidewall of the first trench structure and the second trench structure, and a dielectric layer formed on the first trench structure, the first n+ source region, and the second n+ source region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a cross-sectional diagram of a trench power transistor according to an embodiment of the present invention.

FIG. 2 illustrates a cross-sectional diagram of the trench power transistor shown in FIG. 1 when voltage drop from drain to source is 0.5V.

FIG. 3 illustrates a cross-sectional diagram of the trench power transistor shown in FIG. 1 when voltage drop from drain to source is 1V.

FIG. 4 illustrates a cross-sectional diagram of the trench power transistor shown in FIG. 1 when voltage drop from drain to source is 10V.

FIG. 5 illustrates a cross-sectional diagram of the trench power transistor shown in FIG. 1 when voltage drop from drain to source is 15V.

### DETAILED DESCRIPTION

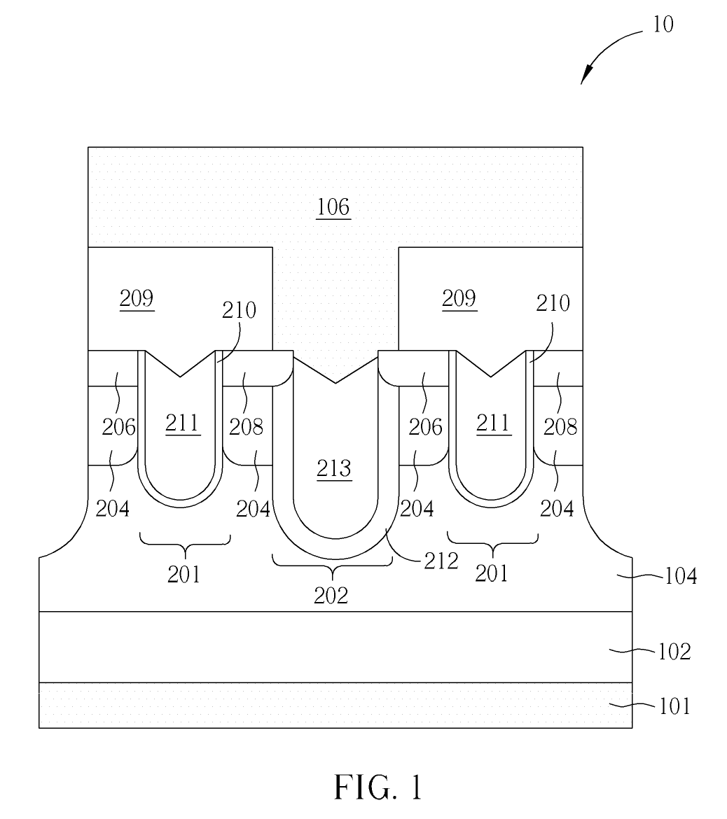

Please refer to FIG. 1, which illustrates a cross-sectional diagram of a trench power transistor 10 according to an embodiment of the present invention. The trench power transistor 10 comprises a backside mental layer 101, a substrate 102, a semiconductor layer 104, and a frontside mental layer 106. The semiconductor layer 104 comprises a first trench structure 201, a second trench structure 202, a p-body region 204, a first n+ source region 206, a second n+ source region 208, and a dielectric layer 209. The first trench structure 201 comprises a gate oxide layer 210 formed around a trench 211 with poly-Si deposited. The second trench structure 202 comprises a p-well junction 212 formed around a trench 213 with a conductive material implanted.

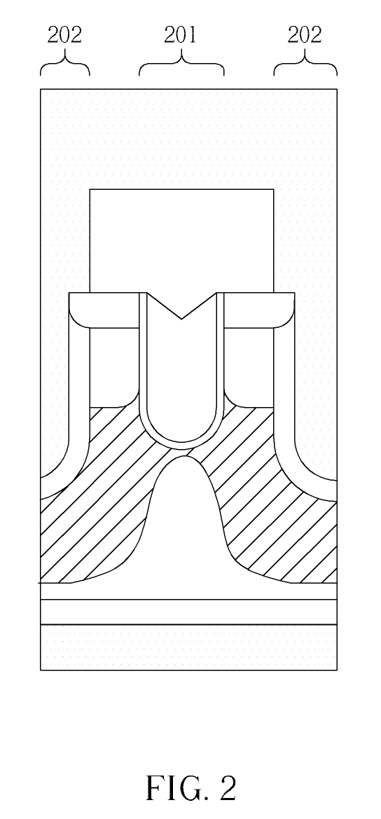

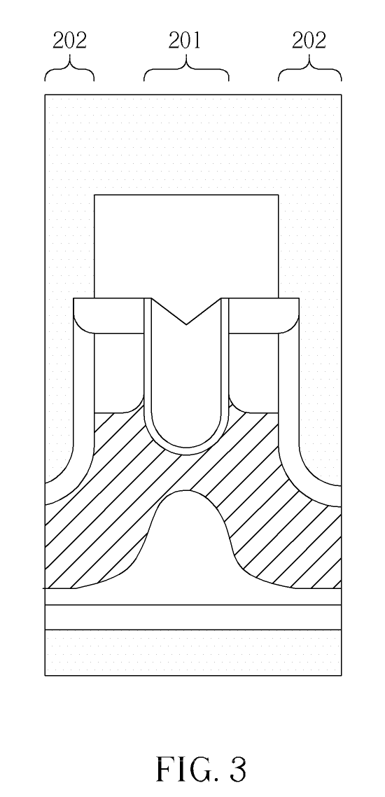

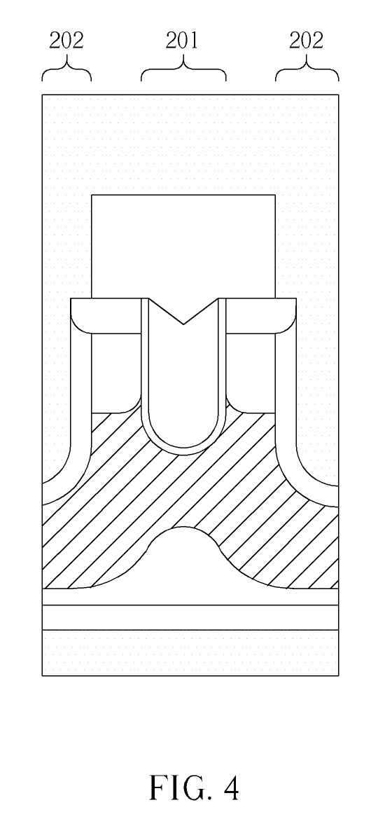

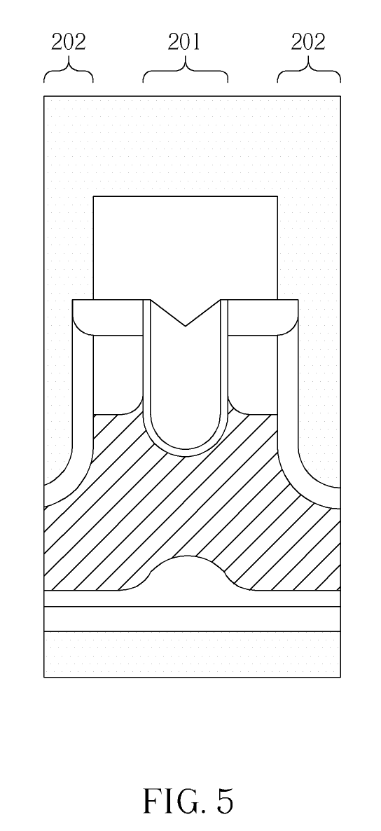

In the semiconductor layer 104, the first trench structure 201 forms a gate of the trench power transistor 10, the first n+ source region 206 and the second n+ source region 208 form sources of the trench power transistor 10, and the backside mental layer 101 forms a drain of the trench power transistor 10. The second trench structures 202 beside the first trench structure 201 pinch the junctions to deepen the depletion region, so that the equivalent width of the dielectric layer can be increased, and the trench power transistor 10 can decrease capacitance between gate and drain accordingly. Please refer to FIG. 2 to FIG. 5, which are cross-sectional diagram of the trench power transistor 10 when voltage drop from the drain (the backside mental layer 101) to the source (the frontside mental layer 106) are 0.5, 1, 10, and 15V. As shown in FIG. 2 to FIG. 5, as the voltage drop increases, the depth of the depletion region increases. In other words, the trench power transistor 10 uses the second trench structures 202 to deepen the depletion region, so as to reduce capacitance.

Preferably, the material of the backside mental layer 101 can be Ti, Ni, or Ag, the material of the frontside mental layer 106 can be Al, the basis material of the semiconductor layer 104 can be epitaxial Si, the material of the dielectric layer 209 can be Boron-Phosphorus glass dielectric material, and the conductive material in the second trench structures 202 can be poly-Si or wolfram (W). Note that, FIG. 1 illustrates the embodiment of the present invention, and those skilled in the art can make modifications accordingly. For example, if the trench power transistor 10 implements an NMOS, the materials of the source regions 206 and 208 are n-type Si, and the material of the body region 204 is p-type Si. Oppositely, if the trench power transistor 10 implements a PMOS, the materials of the source regions 206 and 208 are p-type Si, and the material of the body region 204 is n-type Si.

In summary, via the pinch effect of the second trench structures 202, the trench power transistor 10 can increase the depth of the depletion region, so as to decrease capacitance between gate and drain.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power transistor capable of decreasing capacitance between a gate and a drain comprising:
a backside mental layer;
a substrate formed on the backside mental layer;
a semiconductor layer formed on the substrate, comprising:
a first trench structure comprising a gate oxide layer formed around a first trench with poly-Si implant;
a second trench structure comprising a p-well junction formed around a second trench with conductive material implant;
a p-body region formed outside the first trench structure and the second trench structure;
a first n+ source region formed on the p-body region and beside a sidewall of the first trench structure;
a second n+ source region formed on the p-body region and between another sidewall of the first trench structure and the second trench structure; and
a dielectric layer formed on the first trench structure, the first n+ source region, and the second n+ source region; and
a frontside mental layer formed on the semiconductor layer.

2. The power transistor of claim 1, wherein a material of the backside mental layer is Ti, Ni, or Ag.

3. The power transistor of claim 1, wherein a basis material of the semiconductor layer is epitaxial Si.

4. The power transistor of claim 1, wherein a material of the dielectric layer is Boron-Phosphorus glass dielectric material.

5. The power transistor of claim 1, wherein materials of the first n+ source region and the second n+ source region are n-type Si.

6. The power transistor of claim 1, wherein the conductive material is poly-Si or wolfram (W).

7. The power transistor of claim 1, wherein a material of the frontside mental layer is Al.
